(19) United States
(12) Patent Application Publication
(10) Pub. No.: US 2025/0116348 A1
(43) Pub. Date: Apr. 10, 2025

(54) THROTTLE VALVE FOR SUBSTRATE PROCESSING SYSTEMS

(71) Applicant: LAM RESEARCH CORPORATION, Fremont, CA (US)

(72) Inventor: Andrew BORTH, Newberg, OR (US)

(21) Appl. No.: 18/865,913

(22) PCT Filed: May 19, 2023
(86) PCT No.: PCT/US2023/022909

§ 371 Date: Nov. 14, 2024

Related U.S. Application Data
(60) Provisional application No. 63/346,488, filed on May 27, 2022.

(51) Int. Cl. F16K 31/08; F16K 1/22

(52) U.S. Cl. CPC F16K 31/086; F16K 1/221

(57) ABSTRACT

A valve of a substrate processing system includes a throttle plate configured to adjust gas flow through a gas line. An outer actuator is arranged outside of the gas line. An inner actuator is arranged inside of the gas line and connected to the throttle plate. The outer actuator is magnetically coupled to the inner actuator. Movement the outer actuator causes movement of the inner actuator relative to the gas line to adjust a position of the throttle plate.

### CROSS-REFERENCE TO RELATED APPLICATIONS

This application claims the benefit of U.S. Provisional Application No. 63/346,488 filed on May 27, 2022. The entire disclosure of the above application is incorporated herein by reference.

### FIELD

The present disclosure relates to substrate processing systems, and more particularly to a throttle valve for gas lines of a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. The substrate treatments may include deposition, etching, cleaning and other treatments. Example processes that may be performed on a substrate include, but are not limited to, chemical vapor deposition (CVD), atomic layer deposition (ALD), conductor etch, rapid thermal processing (RTP), ion implant, physical vapor deposition (PVD), and/or other etch, deposition, or cleaning processes.

A substrate may be arranged on a substrate support, such as a pedestal, an electrostatic chuck (ESC), etc. in a processing chamber of the substrate processing system. During processing, gas mixtures including one or more precursors may be introduced into the processing chamber using a showerhead (or other gas delivery device) and plasma may be used to initiate chemical reactions.

A pump and a pneumatically actuated valve are used to control vacuum pressure in the gas lines connected to the processing chamber. Gas lines or forelines are designed with a high conductance for remote plasma cleaning (RPC). In some processes, the downstream valve is restricted (almost closed) to reduce gas flow in the gas line. This leads to a large pressure drop at the outlet of the valve. When the valve is in this position, reactants/particles from the processing chamber are accelerated by the pressure drop at the valve. As a result, the particles/reactants build up in certain locations of the gas line downstream from the valve. Over time, the gas line eventually clogs due to the buildup.

### SUMMARY

A valve of a substrate processing system includes a throttle plate configured to adjust gas flow through a gas line. An outer actuator is arranged outside of the gas line. An inner actuator is arranged inside of the gas line and connected to the throttle plate. The outer actuator is magnetically coupled to the inner actuator. Movement the outer actuator causes movement of the inner actuator relative to the gas line to adjust a position of the throttle plate.

In other features, the outer actuator includes a first magnet. The inner actuator includes a second magnet. One of the outer actuator and the inner actuator includes a first magnet and the other one of the outer actuator and the inner actuator includes ferrous material.

In other features, the outer actuator includes a first block, a second block, and an annular plate connecting the first block and the second block around an outer surface of the gas line. The first block and the second block include bores receiving first and second magnets, respectively. The throttle plate includes a first throttle plate and a second throttle plate. A cylinder is arranged in the gas line.

In other features, radially inner portions of the first throttle plate and the second throttle plate include mounting portions to receive first and second pins extending between side surfaces of the cylinder, respectively. The first throttle plate and the second throttle plate pivot relative to the first and second pins, respectively. The inner actuator includes a first arm, a second arm connected to the first arm and a radially outer edge of the first throttle plate, and a third arm connected to the first arm and a radially outer edge of the second throttle plate.

In other features, the first throttle plate includes a mounting portion on a downstream surface thereof. The second arm extends through the first throttle plate and is connected to the mounting portion of the first throttle plate. The second throttle plate includes a mounting portion on a downstream surface thereof. The third arm extends through the second throttle plate and is connected to the mounting portion of the second throttle plate.

In other features, the first arm includes a first arm portion extending in a radial direction and a second arm portion including a first end connected to the first arm portion and a second end extending in an axial direction.

In other features, the cylinder includes first and second axial slots located on opposite sides of thereof, respectively. The first and second axial slots receive opposite ends of the first arm portion. Opposite ends of the first arm portion include at least one of a magnet and ferrous material. A second end of the second arm portion includes at least one of a magnet and ferrous material. The cylinder includes first and second openings arranged adjacent to the first throttle plate and the second throttle plate.

A valve of a substrate processing system includes a cylinder including first and second axial slots. First and second throttle plates are mounted to the cylinder. An outer actuator is arranged radially outside of the gas line and includes a first block including a first magnet, a second block including a second magnet, and an annular plate connecting the first block and the second block around an outer surface of the gas line. An inner actuator is arranged radially inside of the gas line and includes a first arm including a first arm portion extending in a radial direction, a first end of the first arm portion is arranged in the first axial slot and includes a third magnet, and a second end of the first arm portion is arranged in the second axial slot and includes a fourth magnet. A second arm is connected to the first arm and a radially outer edge of the first throttle plate. A third arm is connected to the first arm and a radially outer edge of the second throttle plate.

In other features, an actuator is configured to selectively move the outer actuator relative to the gas line. The first magnet of the outer actuator is magnetically coupled to the third magnet of the first arm portion. The second magnet of the outer actuator is magnetically coupled to the fourth magnet of the first arm portion. Movement of the actuator causes movement of the outer actuator and the inner actuator relative to the gas line to adjust a position of the first and second throttle plates.

In other features, radially inner portions of a downstream side of the first throttle plate and the second throttle plate include mounting portions to receive first and second pins extending between side surfaces of the cylinder, respectively. The first throttle plate and the second throttle plate pivot relative to the first and second pins, respectively.

In other features, the first arm further includes a second arm portion connected at a first end to the first arm portion and extending in an axial direction. A second end of the second arm portion includes a fifth magnet. The cylinder includes first and second openings arranged adjacent to the first throttle plate and the second throttle plate.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system including a throttle valve according to the present disclosure;

FIGS. 2A and 2B are simplified side cross-sectional views of an example of the throttle valve mounted in a gas line according to the present disclosure;

FIG. 3 is a perspective view of an example of the throttle valve mounted in a gas line according to the present disclosure;

FIG. 4 is a perspective view of an example of the throttle valve according to the present disclosure;

FIG. 5 is a perspective view of an example of a cylinder of the throttle valve according to the present disclosure;

FIG. 6 is a plan view of an example of an arm of the throttle valve according to the present disclosure;

FIG. 7 is a plan view of an example of an annular member of the throttle valve according the present disclosure;

FIG. 8 is a plan view of an example of an arm of the throttle valve according to the present disclosure;

FIG. 9 is a plan view of an example of an inlet of the throttle valve according to the present disclosure;

FIG. 10 is a plan view of an example of an outlet of the throttle valve according to the present disclosure; and

FIGS. 11 and 12 are side cross-sectional views illustrating operation of an example of a throttle valve according to the present disclosure.

In the drawings, reference numbers may be reused to identify similar and/or identical elements.

### DETAILED DESCRIPTION

A pump and a pneumatically actuated downstream valve are typically used to control vacuum pressure in gas lines such as gas lines. Gas lines or forelines are designed with a high conductance for remote plasma cleaning (RPC). During some portions of a process, reduced gas flow is needed. The valve is restricted (almost fully closed) to reduce the flow rate (and vacuum pressure in the gas line). This leads to a large pressure drop at the outlet of the valve. When the valve is in this position, reactants/particles from the processing chamber are accelerated at the outlet of the valve (due to a small opening of the valve and the high pressure drop). Buildup of reactants/particles occurs in certain locations of the gas line downstream from the valve. Over time, the gas line downstream from the valve eventually clogs, which requires disassembly of the gas lines and valve.

A throttle valve according to the present disclosure is arranged in a gas line (such as an exhaust gas line). While the following description relates to use of the throttle valve in an exhaust gas line, the throttle valve can be used in other types of gas lines. When installed in the gas line, the throttle valve may be arranged near the processing chamber and upstream from the valve and pump. The throttle valve includes an outer actuator located outside of the gas line and an inner actuator that is located inside of the gas line. Another actuator moves the outer actuator relative to the gas line. The outer actuator is magnetically coupled to the inner actuator. In other words, magnetic force is created between the inner actuator and outer actuator and the magnetic force causes the inner actuator to move in response to movement of the outer actuator. Movement of the outer actuator causes the inner actuator to move one or more throttle plates to adjust gas flow. The throttle valve controls flow through the gas line in a non-contact manner without requiring holes to be made through the gas line.

The throttle valve allows more precise control of low flow rates and reduces buildup that would otherwise occur downstream from the valve (if the throttle valve was not used). Furthermore, the throttle valve is located close to the processing chamber and is more thoroughly cleaned during remote plasma clean (RPC) due to the proximity to the plasma (as compared to the valve located further downstream). As a result, the processing chamber can be operated for longer periods without maintenance. Furthermore, the throttle valve allows more fine control of the flow rate at lower flow rates.

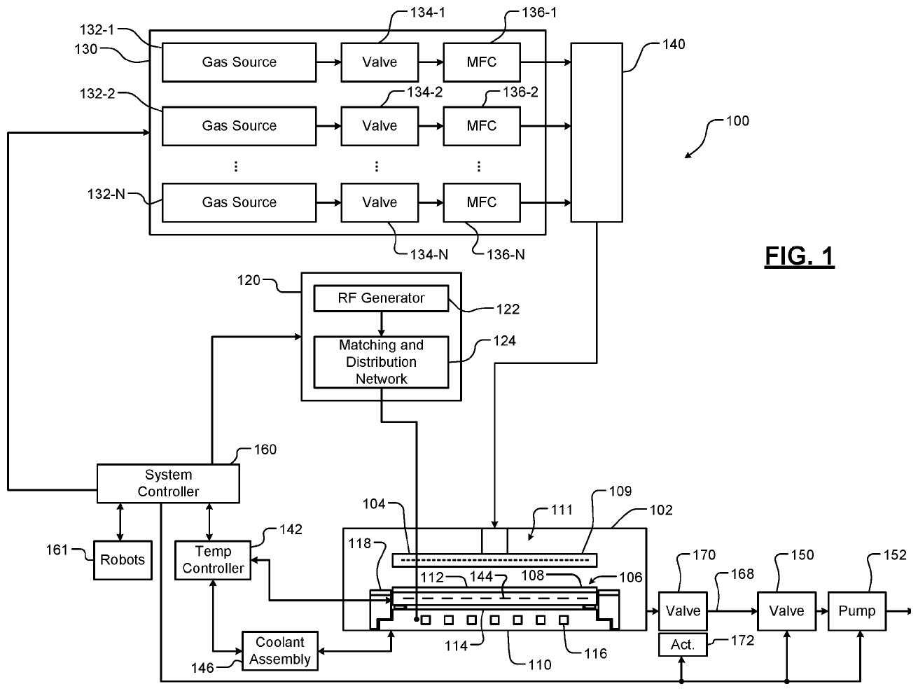

Referring now to FIG. 1, a substrate processing system 100 including a processing chamber 102 that encloses components of the substrate processing system 100 and contains radio frequency (RF) plasma. The processing chamber 102 includes an upper electrode 104 and a substrate support 106, which may be an electrostatic chuck (ESC). During operation, a substrate 108 is arranged on the substrate support 106. While a specific example of the substrate processing system 100 and processing chamber 102 are shown as an example, the principles of the present disclosure may be applied to other types of substrate processing systems and chambers, such as a substrate processing system that uses remote plasma generation and delivery (e.g., using a plasma tube, a microwave tube), etc.

A gas distribution device 111 introduces and distributes process gases. For example only, the upper electrode 104 may be combined with a showerhead 109 (acting as the gas distribution device 111). The showerhead 109 may include a stem portion including one end connected to a top surface of the processing chamber 102. A base portion is generally cylindrical, includes a gas plenum and extends radially outwardly from an opposite end of the stem portion at a location that is spaced from the top surface of the processing chamber 102. A substrate-facing surface or faceplate of the base portion of the showerhead 109 includes holes through which process gas or purge gas flows. Alternately, the upper electrode 104 may include a conducting plate and the process gases may be introduced in another manner.

The substrate support 106 includes a baseplate 110 that is conductive and acts as a lower electrode. The baseplate 110 supports a top plate 112, which may be formed of ceramic. In some examples, the top plate 112 may include one or more heating layers, such as a ceramic multi-zone heating plate. The one or more heating layers may include one or more heating elements, such as conductive traces, as further described below.

A bond layer 114 is disposed between and bonds the top plate 112 to the baseplate 110. The baseplate 110 may include one or more coolant channels 116 for flowing coolant through the baseplate 110. In some examples, the substrate support 106 may include an edge ring 118 that surrounds an outer perimeter of the substrate 108 to shape the plasma.

A radio frequency (RF) generating system 120 generates and outputs voltage to one of the upper electrode 104 and the lower electrode (e.g., the baseplate 110 of the substrate support 106). The other one of the upper electrode 104 and the baseplate 110 may be direct current (DC) grounded, alternating current (AC) grounded, or floating. For example only, the RF generating system 120 may include a voltage generator 122 that generates the voltage that is fed by a matching and distribution network 124 to the baseplate 110. In other examples, the voltage is provided to the upper electrode 104. In other examples, the plasma may be generated inductively or remotely. Although, as shown for example purposes, the RF generating system 120 corresponds to a capacitively coupled plasma (CCP) system, the principles of the present disclosure may also be implemented in other suitable systems, such as transformer coupled plasma (TCP) systems, CCP cathode systems, remote microwave plasma generation and delivery systems, etc.

A gas delivery system 130 includes one or more gas sources 132-1, 132-2, . . . , and 132-N (referred to collectively as gas sources 132), where N is an integer greater than zero. The gas sources supply one or more gas mixtures. The gas sources may also supply purge gas. Vaporized precursor may also be used. The gas sources 132 are connected by valves 134-1, 134-2, . . . , and 134-N (referred to collectively as valves 134) and mass flow controllers 136-1, 136-2, . . . , and 136-N (referred to collectively as mass flow controllers 136) to a manifold 140. A second set of valves (not shown) may be arranged between the mass flow controllers 136 and the manifold 140. An output of the manifold 140 is fed to the processing chamber 102. For example only, the output of the manifold 140 is fed to the showerhead 109.

A temperature controller 142 may be connected to heating elements, such as thermal control elements (TCEs) 144 arranged in the top plate 112. For example, the heating elements may include, but are not limited to, macro heating elements corresponding to respective zones in a multi-zone heating plate and/or an array of micro heating elements disposed across multiple zones of a multi-zone heating plate. The temperature controller 142 may be used to control the heating elements to control a temperature of the substrate support 106 and the substrate 108.

The temperature controller 142 may communicate with a coolant assembly 146 to control coolant flow through the coolant channels 116. For example, the coolant assembly 146 may include a coolant pump and reservoir. The temperature controller 142 operates the coolant assembly 146 to selectively flow the coolant through the coolant channels 116 to cool the substrate support 106.

A valve 150 and pump 152 are connected to a gas line 148 (e.g., an exhaust gas line or another gas line) and are used to control pressure within the processing chamber 102 and/or to evacuate reactants from the processing chamber 102. A controller 160 may be used to control components of the substrate processing system 100. One or more robots 161 may be used to deliver substrates onto, and remove substrates from, the substrate support 106.

A throttle valve 170 is arranged near the processing chamber upstream from the valve 150. Throttle valves include a throttle plate that rotates to different angular positions within a gas channel to vary or adjust gas flowing within the gas channel. The throttle valve 170 is configured to move one or more throttle plates to adjust gas flow through the throttle valve 170. The throttle valve 170 is mounted around the gas line 148 (for example, an exhaust gas line or another gas line) and is moved by an actuator 172 relative to the gas line 148. In some examples, the actuator 172 comprises a linear actuator, a pneumatic actuator, a screw-type actuator, or another type of actuator. The throttle valve 170 opens and closes via magnetic coupling through the gas line 148 as will be described further below.

The throttle valve 170 is connected to the processing chamber upstream from the valve 150 and the pump 152. As a result, the throttle valve 170 is cleaned more thoroughly during a remote plasma clean (RPC) since the plasma has less distance to travel.

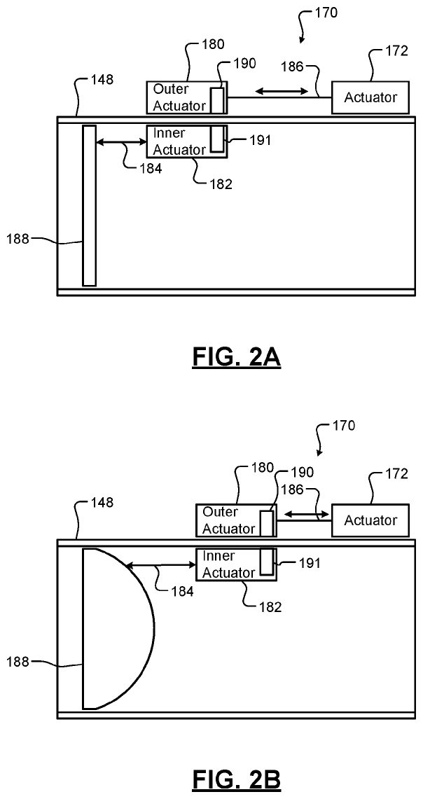

Referring now to FIGS. 2A and 2B, the throttle valve 170 is shown in closed and opened positions, respectively. The throttle valve 170 includes an outer actuator 180 that is located outside of the gas line 148. The outer actuator 180 is magnetically coupled to an inner actuator 182 located inside of the gas line 148. The inner actuator 182 is coupled by linkage 184 to one or more throttle plates 188. The actuator 172 is coupled by linkage 186 to the outer actuator 180. The actuator 172 selectively moves the outer actuator 180 relative to the gas line 148 to adjust a position on the throttle plate 188.

In some examples, both the outer actuator 180 and the inner actuator 182 include an insert 190 and 191, respectively. In some examples, the inserts 190 and 191 of the outer actuator 180 and the inner actuator 182, respectively, include magnets having opposite polarities. In other examples, one of the outer actuator 180 and the inner actuator 182 includes a magnet and the other one of the outer actuator 180 and the inner actuator 182 includes ferrous material that is magnetically attracted to the magnet.

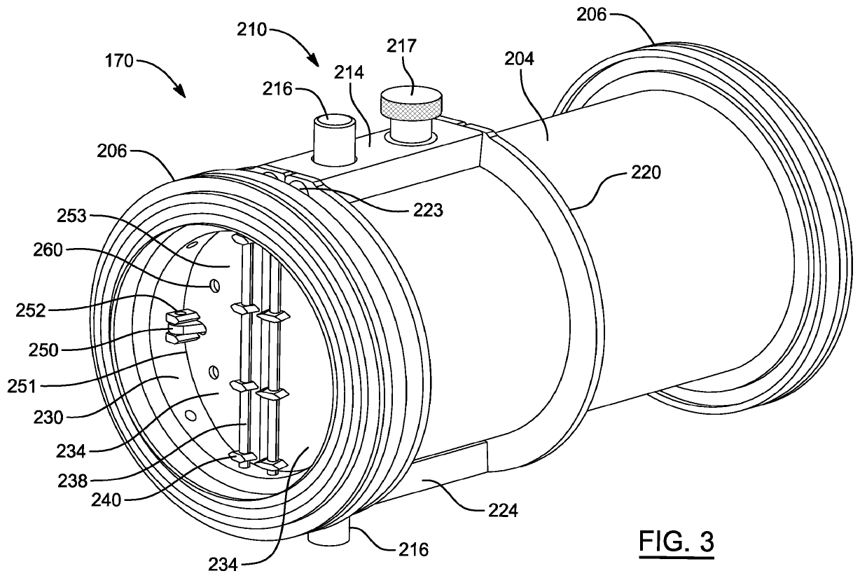

Referring now to FIG. 3, the throttle valve 170 is shown mounted in a gas line 204 having a cylindrical shape and including flanges 206. The throttle valve 170 includes an outer actuator 210 that is moved reciprocally relative an outer surface of the gas line 204 by the actuator 172. The outer actuator 210 includes a block 214 providing a mounting location and including a first bore for receiving a magnet 216 and a second bore for receiving a set screw 217. The set screw 217 can be tightened against an outer surface of the gas line to prevent movement of the throttle valve 170. The outer actuator 210 further includes a block 224 arranged on an opposite side of the gas line 204 and providing another mounting location. Plates 220 extend around and are spaced from the gas line 204. The plates 220 are connected by fasteners 223 to the blocks 214 and 224.

In some examples, the blocks 214 and 224 include mounting bores for receiving magnets, ferrous material and/or fasteners (to connect the plates 220). In some examples, the blocks 214 and 224 include a rectangular-shaped cube, although other shaped blocks may be used. In some examples, the plates 220 include arcuate, semicircular, or ring-like support plates, although other shapes can be used. Opposite ends of pairs of the plates 220 are connected to ends of the blocks 214, 224, respectively, around an outer circumference of the gas or gas line. This arrangement allows the outer actuator 210 to be connected to and removed from the gas or gas line without requiring the gas or gas line to be disassembled.

The throttle valve 170 further includes a cylindrical member or a cylinder 230 arranged inside of the gas line 204. First and second throttle plates 234 have a semi-circular shape and are mounted to (and pivot relative to) opposite side surfaces of the cylinder 230. In some examples, pins 238 extend between the side surfaces of the cylinder 230. The pins 238 are attached by mounting portions 240 to radially inner surfaces of the first and second throttle plates 234. In some examples, each of the mounting portions 240 include a block with a bore that receives the pins 238.

First ends of first and second arms 250 (collectively or individually referred to as arm(s) 250) are attached to radially outer edges 251 of the first and second throttle plates 234. In some examples, the first ends of the first and second arms 250 extend through and are attached to a surface 253 of the first and second throttle plates 234. In some examples, the surface 253 is a downstream surface that faces an outlet of the throttle valve 170 (as compared to an opposite or upstream surface of the first and second throttle plates 234 that faces the inlet of the throttle valve 170). Downstream is in the direction of gas flow and upstream is opposite to the direction of the gas flow. In some examples, mounting portions 252 extend in a direction towards the outlet of the throttle valve from the surface 253 at the radially outer edges 251 of the first and second throttle plates 234. In some examples, each of the mounting portions 252 include a block with a bore that receives the pins 238. In some examples, through holes 260 extend through the first and second throttle plates 234 to provide a base flow rate when the first and second throttle plates are closed.

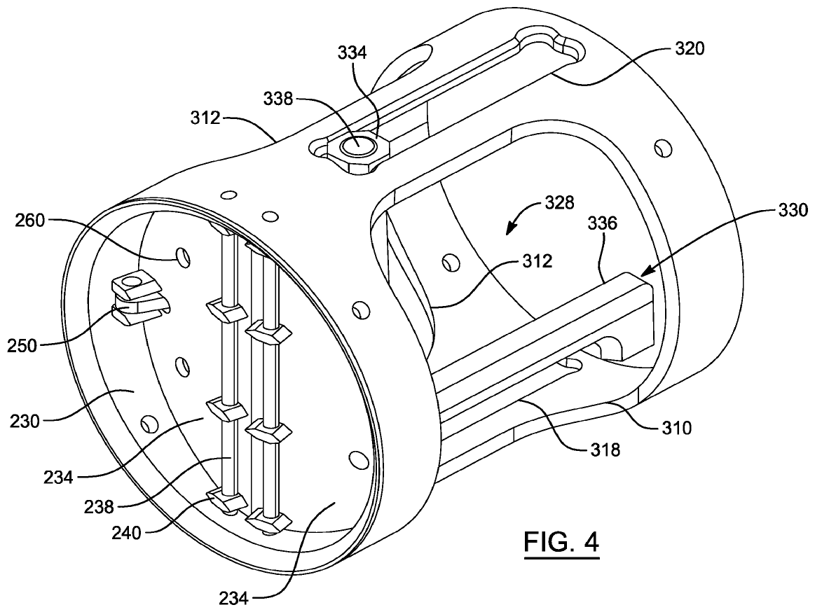

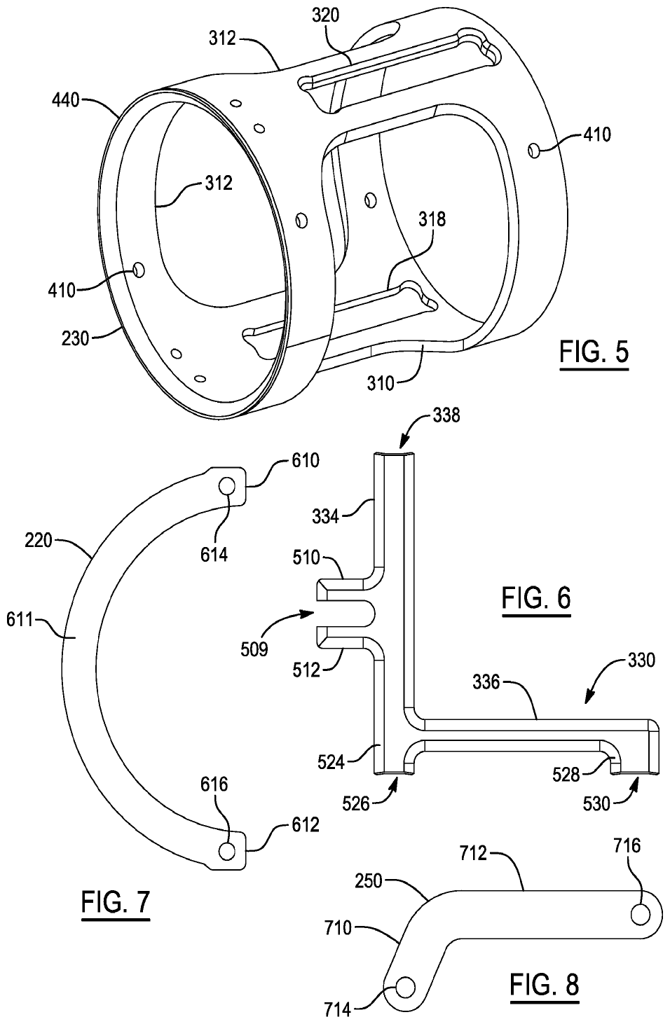

Referring now to FIGS. 4 and 5, the throttle valve 170 is shown. The cylinder 230 of the throttle valve 170 includes arcuate openings 310 and 312 located on opposite sides thereof and slots 318 and 320 located on opposite sides thereof. In some examples, the arcuate openings 310 and 312 are aligned with radially outer edges of the throttle plates and the slots 318 and 320 are rotated 90° relative thereto. The arcuate openings 310 and 312 reduce buildup that would otherwise occur along the radially outer edges of the first and second throttle plates 234 if the openings 310 and 312 were not used.

An inner actuator 328 includes the arms 250 and an arm 330 including a first arm portion 334 and a second arm portion 336. The second arm portion 336 extends in an axial direction and has an “L”-shaped configuration. The first arm portion 334 is connected to the second arm portion 336 and extends in a radial direction. Ends of the first arm portion 334 are received in and guided by the slots 318 and 320 during movement. Magnets 338 are arranged in bores in opposite ends of the first arm portion 334. A magnet (shown below) is also located at an end of the second arm portion 336 that is distally located relative to the first arm portion 334.

In FIG. 5, bores 410 may be arranged at different circumferential positions of the cylinder 230 to allow set screws (not shown) to be used to fix a rotational position of the throttle valve 170 in the gas line 204. A flange 440 extends radially outwardly from one end of the cylinder 230. The flange 440 rests against the flange 206 to prevent axial movement of the throttle valve 170 in a downstream direction after installation.

Referring now to FIG. 6, the arm 330 of the throttle valve 170 is shown. An end 528 of the second arm portion 336 extends radially outwardly and includes a magnet 530 embedded therein. Opposite ends 520 and 524 of the first arm portion 334 include magnets 338 and 526 embedded therein, respectively. A “U”-shaped or concave member 509 includes first and second legs 510 and 512 extending from the first arm portion 334 in a direction opposite to the second arm portion 336. The first and second legs 510 and 512 are spaced from one another. Ends of the arms 250 (FIGS. 3, 4 and 8) are mounted between the first and second legs 510 and 512 of the “U”-shaped member 510.

Referring now to FIG. 7, the plate 220 of the throttle valve 170 is shown. The plate 220 extends between opposite axially facing surfaces the blocks 214 and 224. The plate 220 includes first and second arcuate members 611 including bores 614 and 616 located at ends 610 and 612 thereof, respectively. The bores 614 and 616 receive the fasteners 223.

Referring now to FIG. 8, an example of the first and second arms 250 of the throttle valve 170 is shown. The arm 250 includes a first arm portion 710 and a second arm portion 712. The first arm portion 710 forms an acute angle relative to the second arm portion 712. Bores 714 and 716 are located at opposite ends thereof and receive mounting pins (not shown).

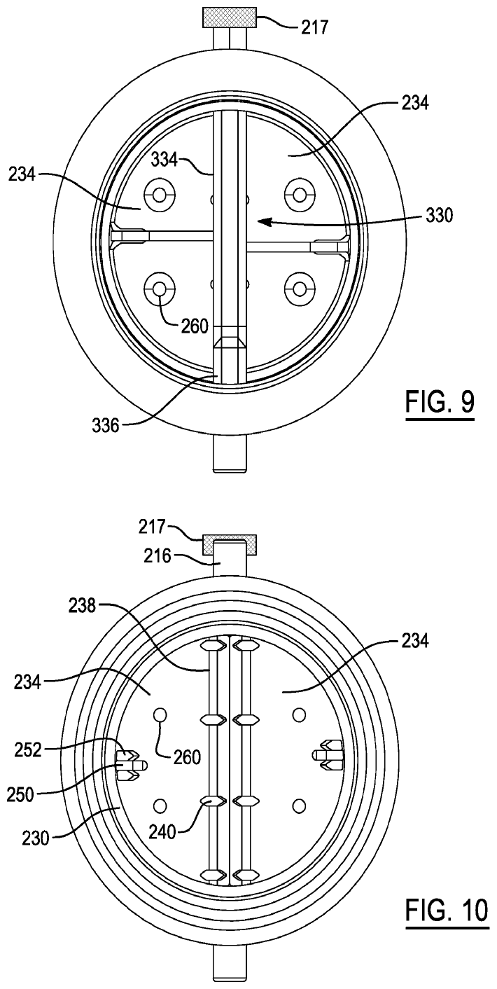

Referring now to FIGS. 9 and 10, an inlet and an outlet of the throttle valve 170 are shown with the first and second throttle plates 234 in a closed position, respectively. In FIG. 9, the first arm portion 334 extends radially across the inner volume of the throttle valve 170. When closed, the first and second throttle plates 234 reduce gas flow other than gas flowing through the through holes 260 (if used). In addition, some gas still flows around radially inner and outer edges of the first and second throttle plates 234.

As can be appreciated, when the throttle valve 170 is fully opened by moving the arm 330 in an upstream direction, radially outer ends of the first and second throttle plates 234 pivot in an upstream direction and the first and second throttle plates 234 are shielded from gas flow by the first arm portion 334, which reduces buildup of reactants and/or particles on the first and second throttle plates 234.

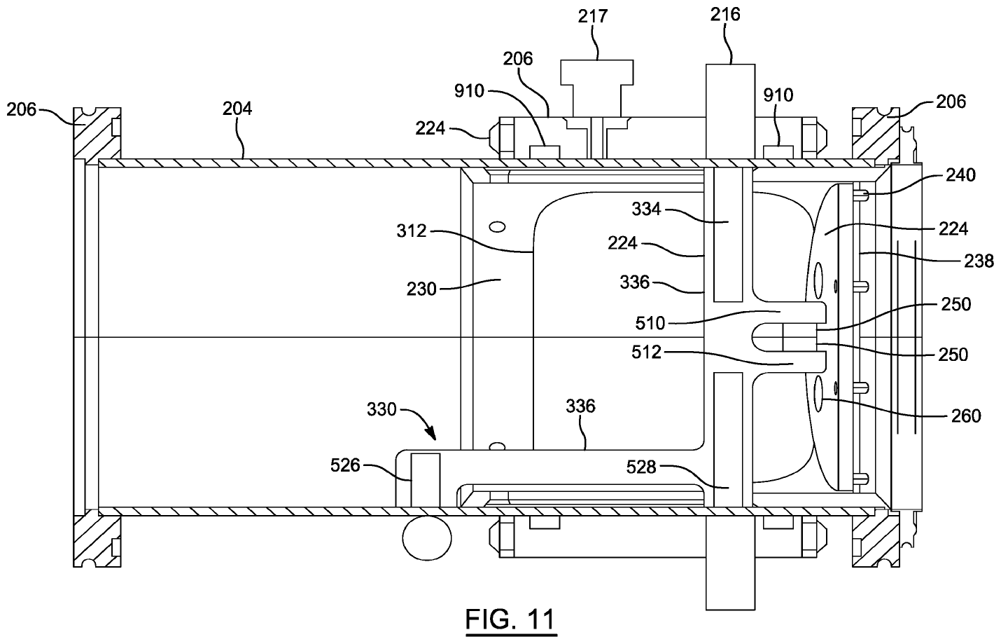

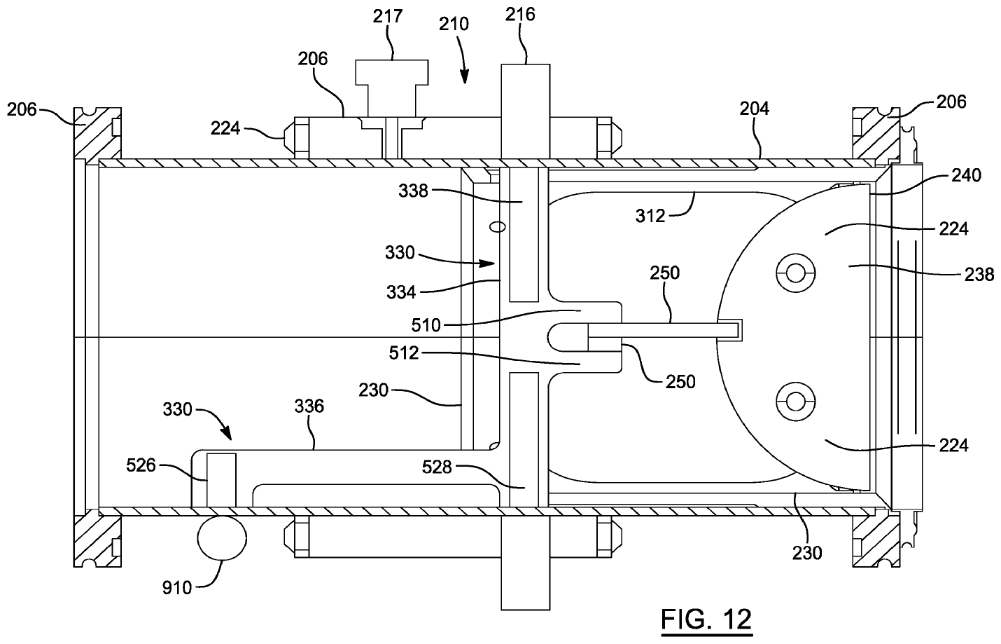

Referring now to FIGS. 11 and 12, the throttle valve 170 is shown in closed and opened positions, respectively. The actuator 172 moves the outer actuator 210 reciprocally in an axial direction. To close the throttle valve 170, the actuator 172 moves in a downstream direction. The magnets 216 in the blocks 214 and 224 move in a downstream direction. In some examples, the blocks 214 and 224 may include bearings 910 to reduce friction. The magnets 338 and 530 in the first arm portion 334 of the arm 330 are magnetically coupled to the magnets 216 in the blocks 214 and 224 of the outer actuator 210. In some examples, the magnet 526 in the end of the second arm portion 336 is magnetically coupled to a ball bearing 920 to provide a visual confirmation of movement of the arm 330 and the first and second throttle plates 234.

To open the throttle valve 170, the actuator 172 moves in an upstream direction. The magnets 216 arranged in the blocks 214 and 224 also move in an upstream direction. The magnets 338 and 530 in the first arm portion 334 of the arm 330 are magnetically coupled to the magnets 216 in the blocks 214 and 224 of the outer actuator 210. The arm 330 moves in the upstream direction. The arm 330 is connected by the arms 250 to radially outer surfaces of the first and second throttle plates 234. In response to the movement of the arm 330 and the arms 250, the first and second throttle plates 234 pivot about the pins 238, which increases gas flow.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements or an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer substrate support, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A valve of a substrate processing system, comprising:
a throttle plate configured to adjust gas flow through a gas line;
an outer actuator arranged outside of the gas line; and
an inner actuator arranged inside of the gas line and connected to the throttle plate;
wherein the outer actuator is magnetically coupled to the inner actuator, and
wherein movement the outer actuator causes movement of the inner actuator relative to the gas line to adjust a position of the throttle plate.

2. The valve of claim 1, wherein:
the outer actuator includes a first magnet; and
the inner actuator includes a second magnet.

3. The valve of claim 1, wherein:
one of the outer actuator and the inner actuator includes a first magnet; and
the other one of the outer actuator and the inner actuator includes a ferrous material.

4. The valve of claim 1, wherein the outer actuator includes:
a first block;
a second block; and
a plate connecting the first block and the second block on opposite sides of an outer surface of the gas line.

5. The valve of claim 4, wherein the first block and the second block include bores receiving first and second magnets, respectively.

6. The valve of claim 1, wherein the throttle plate includes a first throttle plate and a second throttle plate.

7. The valve of claim 6, further comprising a cylinder arranged in the gas line.

8. The valve of claim 7, wherein:
radially inner portions of the first throttle plate and the second throttle plate include mounting portions to receive first and second pins extending between side surfaces of the cylinder, respectively; and
wherein the first throttle plate and the second throttle plate pivot relative to the first and second pins, respectively.

9. The valve of claim 7, wherein the inner actuator includes:
a first arm;
a second arm connected to the first arm and a radially outer edge of the first throttle plate; and
a third arm connected to the first arm and a radially outer edge of the second throttle plate.

10. The valve of claim 9, wherein:
the first throttle plate includes a mounting portion on a downstream surface thereof;
the second arm extends through the first throttle plate and is connected to the mounting portion of the first throttle plate;
the second throttle plate includes a mounting portion on a downstream surface thereof; and
the third arm extends through the second throttle plate and is connected to the mounting portion of the second throttle plate.

11. The valve of claim 9, wherein the first arm includes:
a first arm portion extending in a radial direction; and
a second arm portion including a first end connected to the first arm portion and a second end extending in an axial direction.

12. The valve of claim 11, wherein:
the cylinder includes first and second axial slots located on opposite sides of thereof, respectively, and
the first and second axial slots receive opposite ends of the first arm portion.

13. The valve of claim 11, wherein opposite ends of the first arm portion include at least one of a magnet and ferrous material.

14. The valve of claim 11, wherein a second end of the second arm portion includes at least one of a magnet and ferrous material.

15. The valve of claim 7, wherein the cylinder includes first and second openings arranged adjacent to the first throttle plate and the second throttle plate.

16. A valve of a substrate processing system, comprising:
a cylinder including first and second axial slots;
first and second throttle plates mounted to and pivoting relative to the cylinder;
an outer actuator arranged radially outside of a gas line and including:
a first block including a first magnet;
a second block including a second magnet; and
a plate connecting the first block and the second block on opposite sides of an outer surface of the gas line; and
an inner actuator arranged radially inside of the gas line and including:
a first arm including a first arm portion extending in a radial direction, a first end of the first arm portion is arranged in the first axial slot and includes a third magnet, and a second end of the first arm portion is arranged in the second axial slot and includes a fourth magnet;
a second arm connected to the first arm and a radially outer edge of the first throttle plate; and
a third arm connected to the first arm and a radially outer edge of the second throttle plate.

17. The valve of claim 16, further comprising:
an actuator configured to selective move the outer actuator relative to the gas line, wherein:
the first magnet of the outer actuator is magnetically coupled to the third magnet of the first arm portion;
the second magnet of the outer actuator is magnetically coupled to the fourth magnet of the first arm portion; and
movement of the actuator causes movement of the outer actuator and the inner actuator relative to the gas line to adjust a position of the first and second throttle plates.

18. The valve of claim 16, wherein:
radially inner portions of a downstream side of the first throttle plate and the second throttle plate include mounting portions to receive first and second pins extending between side surfaces of the cylinder, respectively; and
wherein the first throttle plate and the second throttle plate pivot relative to the first and second pins, respectively.

19. The valve of claim 16, wherein:
the first arm further includes a second arm portion connected at a first end to the first arm portion and extending in an axial direction; and
a second end of the second arm portion includes a fifth magnet.

20. The valve of claim 16, wherein the cylinder includes first and second openings arranged adjacent to the first throttle plate and the second throttle plate.
